(19) United States
(12) Patent Application Publication
(10) Pub. No.: US 2022/0136097 A1
(43) Pub. Date: May 5, 2022

(54) SPUTTERING TARGET

(71) Applicant: MITSUBISHI MATERIALS CORPORATION, Tokyo (JP)

(72) Inventors: Yuichi Kondo, Sanda-shi (JP); Yujiro Hayashi, Sanda-shi (JP); Masahiro Shoji, Sanda-shi (JP)

(73) Assignee: MITSUBISHI MATERIALS CORPORATION, Tokyo (JP)

(21) Appl. No.: 17/427,120

(22) PCT Filed: Oct. 1, 2019
(86) PCT No.: PCT/JP2019/038675

§ 371 Date: Jul. 30, 2021

(30) Foreign Application Priority Data
Feb. 20, 2019 (JP) 2019-028049
Sep. 26, 2019 (JP) 2019-175893

(51) Int. Cl. C23C 14/34; C23C 14/06

(52) U.S. Cl. CPC C23C 14/3414; C23C 14/0623

(57) ABSTRACT

A sputtering target according to the present invention contains an intermetallic compound formed of Ge, Sb, and Te in an amount of 75 mol % or more, in which a crystallite size of the intermetallic compound is 400 Å or more and 800 Å or less. The sputtering target according to the present invention may further contain one or more additive elements selected from B, C, In, Ag, Si, Sn, and S, in which a total amount of the additive elements is 25 mol % or less.

### TECHNICAL FIELD

The present invention relates to a sputtering target used for forming a Ge—Sb—Te alloy film which can be used as a recording film of a phase-change recording medium or a semiconductor non-volatile memory, for example.

The present application claims priority on Japanese Patent Application No. 2019-028049 filed on Feb. 20, 2019, and Japanese Patent Application No. 2019-175893 filed on Sep. 26, 2019, the contents of which are incorporated herein by reference.

### BACKGROUND ART

Generally, in a phase-change recording medium such as a DVD-RAM, a semiconductor non-volatile memory (phase-change RAM (PCRAM)), and the like, a recording film made of a phase-change material is used. In such a recording film made of a phase-change material, reversible phase-change between crystal and amorphous is caused by heating by laser light irradiation or Joule heat and the difference of reflectivity or electrical resistance between crystal and amorphous is made to correspond to 1 and 0; and thereby, non-volatile storage is realized.

As a recording film made of a phase-change material, a Ge—Sb—Te alloy film is widely used.

The Ge—Sb—Te alloy film described above is formed using a sputtering target which contains Ge, Sb, and Te, for example, as shown in Patent Documents 1 to 5.

The sputtering target disclosed in Patent Documents 1 to 5 is manufactured by a so-called powder sintering method in which an ingot of a Ge—Sb—Te alloy having a desired composition is prepared, the ingot is pulverized to obtain a Ge—Sb—Te alloy powder, and the obtained Ge—Sb—Te alloy powder is subjected to pressure sintering.

### PRIOR ART DOCUMENTS

### Patent Document

Patent Document 1: Japanese Patent No. 4172015

Patent Document 2: Japanese Patent No. 4300328

Patent Document 3: Japanese Patent No. 4766441

Patent Document 4: Japanese Patent No. 5396276

Patent Document 5: Japanese Patent No. 5420594

### DISCLOSURE OF INVENTION

### Problems to be Solved by the Invention

As disclosed in Patent Documents 1 to 5, in a case in which the sputtering target of the Ge—Sb—Te alloy is manufactured by the powder sintering method, the crystallization of a sintered material progresses by the thermal history of a sintering step, a heat treatment step after sintering, and the like.

In a case in which the crystallization progresses more than necessary, a fine grain phase does not sufficiently remain in the sintered material, and the strain generated between the crystal grains is accumulated without being released, and due to this strain, there is a risk that breaking of the sputtering target occurs during handling or sputtering.

On the other hand, in a case in which the progress of the crystallization is insufficient, sintering does not progress sufficiently, the mechanical strength is insufficient, and there is a risk that breaking of the sputtering target occurs during handling or sputtering.

The present invention has been made in view of the circumstances described above, and the present invention aims to provide a sputtering target in which the crystallization progresses appropriately, the occurrence of breaking during handling or sputtering can be suppressed, and a Ge—Sb—Te alloy film can be formed stably.

### Solutions for Solving the Problems

As a result of diligent studies by the present inventors in order to solve the above problems, the following matters have been found. In a case in which a sputtering target made of a Ge—Sb—Te alloy is manufactured by the powder sintering method and a specific intermetallic compound consisting of Ge, Sb, and Te is formed, the thermal history such as the sintering step, the heat treatment step after sintering, and the like is controlled such that the crystallite size of the intermetallic compound consisting of Ge, Sb, and Te is in a certain range. Thereby, the crystallization state of the sintered material is optimized and the occurrence of breaking during handling or sputtering can be suppressed.

The present invention has been made based on the above findings, and a sputtering target according to an aspect of the present invention contains an intermetallic compound formed of Ge, Sb, and Te in an amount of 75 mol % or more, in which a crystallite size of the intermetallic compound is in a range of 400 Å or more and 800 Å or less.

According to the sputtering target of the present invention, the crystallite size of the intermetallic compound formed of Ge, Sb, and Te contained in an amount of 75 mol % or more is in a range of 400 Å or more and 800 Å or less, so that a certain amount of fine grain phases remain, and the accumulation of strain between the crystal grains is suppressed. In addition, sintering progresses sufficiently, and mechanical strength is ensured.

Therefore, the occurrence of breaking during handling or sputtering can be suppressed, and the Ge—Sb—Te alloy film can be stably formed.

Examples of the intermetallic compound formed of Ge, Sb, and Te include Ge₂Sb₂Te₅, GeSb₂Te₄, Ge₂Sb₄Te₇, and the like.

Further, the crystallite size of the intermetallic compound formed of Ge, Sb, and Te can be obtained from the X-ray diffraction pattern in the XRD measurement by the following Scherrer equation. Note that β and θ are obtained from the maximum peak.

$$τ = \frac{K \cdot λ}{β \cdot cos θ}$$

K: shape factor (calculated as 0.9)

λ: X-ray wavelength

β: full width at half maximum of peak (FWHM, in radians)

θ: Bragg's number

τ: crystallite size (average size of crystallites)

The sputtering target according to the aspect of the present invention may further contain one or more additive elements selected from B, C, In, Ag, Si, Sn, and S, in which a total amount of the additive elements is 25 mol % or less.

In this case, various characteristics of the sputtering target and the formed Ge—Sb—Te alloy film can be improved by appropriately adding the additive elements described above, and thus the additive elements may be added appropriately in accordance with the required characteristics. For example, by adding the elements described above, an appropriate chemical, optical, and electrical response can be obtained as a recording material.

Further, in a case in which the additive elements described above are added, the influence of the sputtering target on the crystallization can be suppressed by limiting the total amount of the additive elements to 25 mol % or less.

### Effects of Invention

According to the present invention, it is possible to provide a sputtering target in which the crystallization progresses appropriately, the occurrence of breaking during handling or sputtering can be suppressed, and a Ge—Sb—Te alloy film can be stably formed.

### BRIEF DESCRIPTION OF DRAWINGS

FIG. 1 is a diagram showing results of XRD measurement of sputtering targets of Examples 1 and 2 (Embodiments 1 and 2) of the present invention.

FIG. 2 is a flowchart showing a method of manufacturing the sputtering target according to the embodiment of the present invention.

### EMBODIMENTS FOR CARRYING OUT THE INVENTION

Hereinafter, a sputtering target according to an embodiment of the present invention will be described with reference to the drawings.

The sputtering target according to the present embodiment is used, for example, when a Ge—Sb—Te alloy film used as a phase-change recording film of a phase-change recording medium or a semiconductor non-volatile memory is formed.

The sputtering target according to the present embodiment contains Ge, Sb, and Te as main components, and contains an intennetallic compound formed of Ge, Sb, and Te in an amount of 75 mol % or more.

Examples of the intermetallic compound formed of Ge, Sb, and Te include Ge₂Sb₂Te₅, GeSb₂Te₄ and the like. In the present embodiment, Ge₂Sb₂Te₅ is contained in an amount of 75 mol % or more.

In the present embodiment, the intermetallic compound formed of Ge, Sb, and Te is preferably contained in an amount of 80 mol % or more, more preferably contained in an amount of 85 mol % or more, and still more preferably contained in an amount of 90 mol % or more.

Mol % of the intermetallic compound formed of Ge, Sb, and Te can be measured as follows.

First, it is confirmed that the intermetallic compound formed of Ge, Sb, and Te is present in the XRD pattern of the sputtering target.

Next, an amount of each additive element is measured by ICP analysis or gas analysis. Then, the total amount of the intermetallic compound formed of Ge, Sb, and Te is obtained by subtracting the total amount of each of these elements from the whole composition.

Then, the amount of the intermetallic compound formed of Ge, Sb, and Te is converted into mol % in accordance with a composition ratio of Ge, Sb, and Te which is confirmed in the XRD pattern.

In the sputtering target according to the present embodiment, the crystallite size of the intermetallic compound formed of Ge, Sb, and Te (in the present embodiment, Ge₂Sb₂Te₅) is in a range of 400 Å or more and 800 Å or less.

The crystallite size of the intermetallic compound formed of Ge, Sb, and Te can be obtained from the X-ray diffraction pattern in the XRD measurement by the Scherrer equation described above.

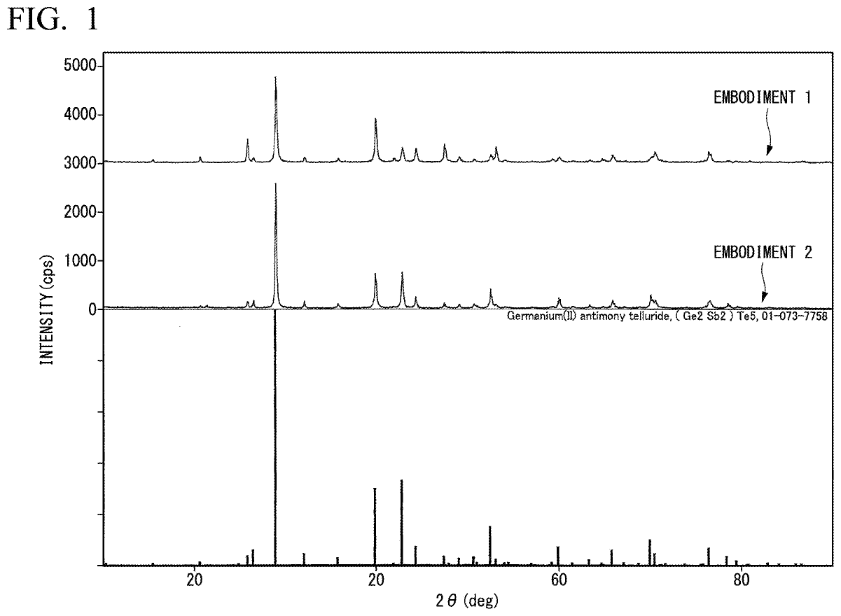

FIG. 1 shows the results of XRD measurement of the sputtering target according to the present embodiment. FIG. 1 shows the results of XRD measurement (X-ray diffraction pattern) of two sputtering targets, the sputtering target according to Embodiment 1 described on the upper side and the sputtering target according to Embodiment 2 described on the lower side.

The sputtering targets according to Embodiment 1 and Embodiment 2 have maximum peaks at the same positions, and both are the intermetallic compounds formed of Ge, Sb, and Te. Further, the crystallite sizes of the intermetallic compounds formed of Ge, Sb, and Te (in the present embodiment, Ge₂Sb₂Te₅) calculated from the half widths of the maximum peaks by the Scherrer equation described above are in the range of 400 Å or more and 800 Å or less.

In FIG. 1, in a case in which the X-ray diffraction pattern in Embodiment 1 and the X-ray diffraction pattern in Embodiment 2 are compared, the maximum peak intensity in Embodiment 2 is higher than the maximum peak intensity in Embodiment 1, and the half width of the maximum peak is small. Therefore, the crystallite size calculated by the Scherrer equation described above in Embodiment 2 is larger than that in Embodiment 1. That is, the crystallization progresses more in Embodiment 2 than in Embodiment 1.

In the sputtering target according to the present embodiment, it is preferable that a lower limit of the crystallite size of the intermetallic compound formed of Ge, Sb, and Te be 590 Å or more.

Further, it is preferable that an upper limit of the crystallite size of the intermetallic compound formed of Ge, Sb, and Te be 735 Å or less.

Further, the sputtering target according to the present embodiment may contain, in addition to Ge, Sb, and Te, one or more additive elements selected from B, C, In, Ag, Si, Sn, and S as necessary. In a case in which the additive elements described above are added, the total amount of these additive elements is set to 25 mol % or less.

In a case in which the additive elements are added in the sputtering target of the present embodiment, the total amount thereof is preferably 20 mol % or less, and more preferably 15 mol % or less. Further, the lower limit value of the additive element is not particularly limited, but in order to reliably improve various characteristics, the lower limit value thereof is preferably 3 mol % or more, and more preferably 5 mol % or more.

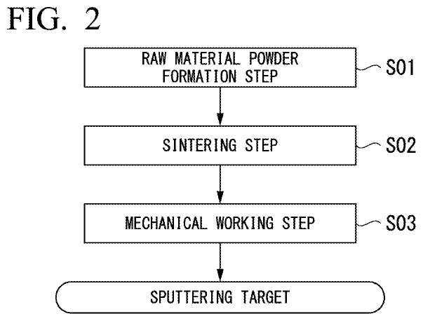

Next, a method of manufacturing the sputtering target according to the present embodiment will be described with reference to the flowchart of FIG. 2. (Raw Material Powder Formation Step S01)

First, a Ge raw material, a Sb raw material, and a Te raw material are weighed to have a predetermined blending ratio. It is preferable that the Ge raw material, the Sb raw material, and the Te raw material having a purity of 99.9 mass % or more be used.

The blending ratio of the Ge raw material, the Sb raw material, and the Te raw material is set in accordance with the composition ratio of the intermetallic compound formed of Ge, Sb, and Te (in the present embodiment, Ge₂Sb₂Te₅). It is preferable that the blending ratio of each of the Ge raw material, the Sb raw material, and the Te raw material be adjusted to be within ±5 atomic % of the targeted theoretical composition ratios.

The Ge raw material, the Sb raw material, and the Te raw material weighed as described above are charged into a melting furnace and molten. The Ge raw material, the Sb raw material, and the Te raw material are molten in vacuum or in an inert gas atmosphere (for example, Ar gas). In the case in which the materials are molten in vacuum, it is preferable that the degree of vacuum be set to 10 Pa or less. In the case in which the materials are molten in an inert gas atmosphere, it is preferable to perform vacuum replacement up to 10 Pa or less, and then introduce an inert gas (for example, Ar gas).

Then, the obtained molten metal is poured into a casting mold to obtain a Ge—Sb—Te alloy ingot. The casting method is not particularly limited.

The Ge—Sb—Te alloy ingot is pulverized in an inert gas atmosphere to obtain a Ge—Sb—Te alloy powder (raw material powder) which has an average particle size D50 of 0.1 μm or more and 120 μm or less. The pulverizing method of the Ge—Sb—Te alloy ingot is not particularly limited, but a vibration mill device is used in the present embodiment. It is preferable that the average particle size D50 of the raw material powder be 10 μm or more and 50 μm or less.

In a case in which the additive elements described above are added, the powder containing the additive element is mixed with the obtained Ge—Sb—Te alloy powder. The mixing method is not particularly limited, but a ball mill device is used in the present embodiment.

(Sintering Step S02)

Next, a mold is filled with the raw material powder obtained as described above, and the raw material powder is heated and sintered while being pressed to obtain the sintered material. As the sintering method, hot pressing, HIP, or the like can be applied.

The sintering temperature (maximum reaching temperature) in the sintering step S02 is set in accordance with a melting point of the obtained intermetallic compound formed of Ge, Sb, and Te. The sintering temperature (maximum reaching temperature) in the sintering step S02 is set to, for example, about 0° C. to −30° C. from a melting point. In the present embodiment, the intermetallic compound is Ge₂Sb₂Te₅, and thus the sintering temperature (maximum reaching temperature) in the sintering step S02 is in a range of 560° C. or higher and 590° C. or lower.

In a case in which the holding time at the sintering temperature (maximum reaching temperature) is less than 3 hours, sintering is insufficient, so that the crystallite size of the intermetallic compound formed of Ge, Sb, and Te in the obtained sintered material is less than 400 Å, the mechanical strength is insufficient, and there is a risk that breaking occurs during handling or sputtering.

On the other hand, in a case in which the holding time at the sintering temperature (maximum reaching temperature) is 15 hours or more, sintering progresses more than necessary, so that the crystallite size of the intermetallic compound formed of Ge, Sb, and Te in the obtained sintered material exceeds 800 Å, the microcrystal region becomes narrow, the stress relaxation effect becomes insufficient, and there is a risk that breaking occurs during handling or sputtering.

Therefore, in the present embodiment, the holding time at the sintering temperature (maximum reaching temperature) in the sintering step S02 is set in a range of 3 hours or more and less than 15 hours.

The lower limit of the holding time at the sintering temperature (maximum reaching temperature) in the sintering step S02 is preferably 4 hours or more, and more preferably 5 hours or more. On the other hand, the upper limit of the holding time at the sintering temperature (maximum reaching temperature) in the sintering step S02 is preferably 12 hours or less, and more preferably 10 hours or less.

Further, it is preferable that the applied pressure in the sintering step S02 be in a range of 50 kgf/cm² or more and 150 kgf/cm² or less.

(Mechanical Working Step S03)

Next, the obtained sintered material is subjected to mechanical working to have a predetermined size.

The sputtering target according to the present embodiment is manufactured by the steps described above.

The sputtering target according to the present embodiment having the configuration described above contains Ge, Sb, and Te as the main components, and contains the intermetallic compound formed of Ge, Sb, and Te in an amount of 75 mol % or more, in which the crystallite size of the intermetallic compound formed of Ge, Sb, and Te is 400 Å or more, and thus sintering progresses sufficiently and the mechanical strength is sufficiently ensured.

On the other hand, the crystallite size of the intermetallic compound formed of Ge, Sb, and Te is 800 Å or less, sintering does not progress more than necessary, a certain amount of fine grains remains, the accumulation of strain between crystal grains is suppressed, and a stress relaxation effect can be achieved.

Therefore, the occurrence of breaking during handling or sputtering can be suppressed, and the Ge—Sb—Te alloy film can be stably formed.

Further, in a case in which the sputtering target of the present embodiment contains one or more additive elements selected from B, C, In, Ag, Si, Sn, and S and the total amount of the additive elements is 25 mol % or less, it is possible to improve various characteristics of the sputtering target and the formed Ge—Sb—Te alloy film and it is possible to suppress the influence of the sputtering target on the crystallization during sintering.

Further, in the present embodiment, in the sintering step S02, the sintering temperature (maximum reaching temperature) is different in accordance with the melting point of the obtained intermetallic compound formed of Ge, Sb, and Te, and the holding time at this sintering temperature (maximum reaching temperature) is 3 hours or more, so that sintering progresses sufficiently and the crystallite size of the intermetallic compound formed of Ge, Sb, and Te in the sintered material can be set to 400 Å or more.

On the other hand, the holding time at the sintering temperature (maximum reaching temperature) is less than 15 hours, so that sintering does not progress more than necessary, and the crystallite size of the intermetallic compound formed of Ge, Sb, and Te in the sintered material can be set to 800 Å or less.

Therefore, the sputtering target according to the present embodiment can be satisfactorily manufactured.

The embodiments of the present invention have been described above, but the present invention is not limited to these, and can be appropriately changed without departing from the technical features of the present invention.

For example, in the present embodiment, it has been described that Ge₂Sb₂Te₅ is provided as the intermetallic compound formed of Ge, Sb, and Te, but the present invention is not limited to this, and another intermetallic compound such as Ge₁Sb₂Te₄ may be provided as the intermetallic compound formed of Ge, Sb, and Te.

### EXAMPLES

Hereinafter, the results of confirmation experiments performed to confirm the effectiveness of the present invention will be described.

(Sputtering Target)

As the molten raw materials, the Ge raw material, the Sb raw material, and the Te raw material, each having a purity of 99.9 mass % or more were prepared.

The Ge raw material, the Sb raw material, and the Te raw material were weighed in the blending ratio of the intermetallic compound formed of Ge, Sb, and Te shown in Table 1.

The weighed Ge raw material, the Sb raw material, and the Te raw material were charged into the melting furnace and made molten in the Ar gas atmosphere, and the obtained molten metal was poured into the casting mold to obtain the Ge—Sb—Te alloy ingot.

The obtained Ge—Sb—Te alloy ingot was pulverized in the Ar gas atmosphere to obtain the Ge—Sb—Te alloy powder (raw material powder). The average particle size D50 of the Ge—Sb—Te alloy powder (raw material powder) was 10 μm.

In a case in which the additive elements shown in Table 1 were added, predetermined amounts of the additive element powders were mixed with the Ge—Sb—Te alloy powder described above by using the ball mill device.

A carbon hot pressing mold was filled with the obtained raw material powder, the obtained raw material powder was held in a vacuum atmosphere at the sintering temperature (maximum reaching temperature) and the holding time at the sintering temperature shown in Table 1, and was sintered through pressing (hot pressing) to obtain the sintered material. The applied pressure was 100 kgf/cm².

The obtained sintered material was subjected to mechanical working to manufacture the sputtering target (126 mm×178 mm×6 mm) for evaluation. The following items were evaluated.

(X-ray Diffraction Analysis)

A specimen for measuring the X-ray diffraction pattern was collected from the obtained sputtering target, the X-ray diffraction analysis (XRD) was performed under the following conditions, and the maximum peak position 2θ derived from the intermetallic compound formed of Ge, Sb, and Te and the half width β of the maximum peak were measured. Table 1 shows the results of measurement.

Device: manufactured by Rigaku Corporation (RINT-Ultima III)

tube bulb: Cu

tube voltage: 40 kV

tube current: 40 mA

scanning range (2θ): 10° to 90°

slit size: divergence (DS) ⅔ degree, scattering (SS) ⅔ degree, light-receiving (RS) 0.8 mm

measurement step width: 0.04 degrees at 2θ

scan speed: 4 degrees per minute

specimen table rotation speed: 30 rpm

(Crystallite Size)

From the half width of the maximum peak measured by the X-ray diffraction analysis described above, the crystallite size τ was calculated using the Scherrer equation described above. Table 1 shows the calculated crystallite size τ. In the calculation, a CuKβ ray was excluded by a light-receiving monochromator, a CuKα2 ray was excluded by software, and the half width of the maximum peak of a CuKα1 ray was used.

(Breaking During Mechanical Working)

The sintered material described above was subjected to working using a lathe under the conditions that a rotation speed was 250 rpm and a feed was 0.1 mm and the situation of the occurrence of chipping or cracking during working was confirmed.

A case in which no chipping or cracking was confirmed was evaluated as “A”, and a case in which sputtering was impossible due to chipping or cracking was evaluated as “B”. Table 1 shows the evaluation results.

TABLE 1

| | | | | | | | | X-ray diffraction | | | |
|---|---|---|---|---|---|---|---|---|---|---|---|
| | | Composition ratio | | | | Sintering condition | | Maximum | | | Breaking |
| | | Ge, Sb, Te | | Additive element | | Sintering | Holding | peak | Half | | during |
| | | Intermetallic | Amount | | Amount | temperature | time | position | width | Crystallite | mechanical |
| | | compound | (mol %) | Element | (mol %) | (° C.) | (hour) | 2θ (°) | β (°) | size τ (Å) | working |
| Invention | 1 | Ge₂Sb₂Te₅ | 100.0 | — | — | 580 | 5 | 29.0 | 0.138 | 595 | A |
| Example | 2 | Ge₂Sb₂Te₅ | 100.0 | — | — | 580 | 10 | 28.9 | 0.112 | 732 | A |
| | 3 | Ge₂Sb₂Te₅ | 75.0 | C | 25.0 | 580 | 10 | 29.0 | 0.118 | 695 | A |
| | 4 | Ge₂Sb₂Te₅ | 75.0 | Si | 25.0 | 580 | 10 | 29.0 | 0.175 | 469 | A |
| Comparative | 1 | Ge₂Sb₂Te₅ | 100.0 | — | — | 580 | 1 | 29.0 | 0.223 | 368 | B |
| example | 2 | Ge₂Sb₂Te₅ | 100.0 | — | — | 580 | 20 | 29.0 | 0.097 | 846 | B |
| | 3 | Ge₂Sb₂Te₅ | 70.0 | C | 30.0 | 580 | 10 | 29.0 | 0.123 | 667 | B |

In Comparative Example 1 in which the holding time at the sintering temperature (maximum reaching temperature) was 1 hour in the sintering step, the crystallite size of Ge₂Sb₂Te₅ was 368 Å, which was smaller than the range of the present invention, and breaking was confirmed in the sputtering target. It is presumed that sintering was insufficient and the mechanical strength was insufficient.

In Comparative Example 2 in which the holding time at the sintering temperature (maximum reaching temperature) was 20 hours in the sintering step, the crystallite size of Ge₂Sb₂Te₅ was 846 Å, which was larger than the range of the present invention, and breaking was confirmed in the sputtering target. It is presumed that sintering progresses more than necessary, the fine grain phases did not sufficiently remain, and strain was accumulated between the crystal grains.

In Comparative Example 3 in which 30 mol % of C was contained as an additive element, the crystallite size was in the range of 400 Å or more and 800 Å or less, but the ratio of the additive element was large, the strain-relaxing effect of the Ge₂Sb₂Te₅ crystal grains became insufficient, and breaking was confirmed in the sputtering target.

On the other hand, in Invention Examples 1 and 2 in which the crystallite size of Ge₂Sb₂Te₅ was in the range of 400 Å or more and 800 Å or less, no breaking was confirmed in the sputtering target.

Further, in Invention Example 3 in which 25 mol % of C was contained as the additive element and Invention Example 4 in which 25 mol % of Si was contained as the additive element, no breaking was confirmed in the sputtering target.

As described above, according to Invention Examples, it was confirmed that it is possible to provide a sputtering target in which the crystallization progresses appropriately, the occurrence of breaking during handling or sputtering can be suppressed, and a Ge—Sb—Te alloy film can be stably formed.

### INDUSTRIAL APPLICABILITY

According to the present invention, it is possible to provide a sputtering target in which crystallization progresses appropriately, the occurrence of breaking during handling or sputtering can be suppressed, and a Ge—Sb—Te alloy film can be stably formed.

What is claimed is:

1. A sputtering target comprising an intermetallic compound formed of Ge, Sb, and Te in an amount of 75 mol % or more,
wherein a crystallite size of the intermetallic compound is 400 Å or more and 800 Å or less.

2. The sputtering target according to claim 1, further comprising one or more additive elements selected from B, C, In, Ag, Si, Sn, and S,
wherein a total amount of the additive elements is 25 mol % or less.
